(19) United States
(12) Patent Application Publication
(10) Pub. No.: US 2008/0212246 A1
(43) Pub. Date: Sep. 4, 2008

(54) Systems and Methods for Detecting Shorts in Electrical Distribution Systems

(75) Inventors: Toru Tanaka, Plano, TX (US); Kazuya Kobayashi, Tokyo (JP); Hiroyuki Ueyama, Oita (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/967,087

(22) Filed: Dec. 29, 2007

Related U.S. Application Data
(60) Provisional application No. 60/883,025, filed on Dec. 31, 2006.

(51) Int. Cl. H02H 3/28; G01R 31/02

(52) U.S. Cl. 361/86; 324/754

(57) ABSTRACT

Systems and methods for detecting a short in an electrical distribution system are disclosed. In one embodiment, a determination is made as to whether a short condition is satisfied based on a change in a voltage in a wire harness coupled to a first side of a switch. The determination of whether a short exists is made in response to determining whether the short condition has been satisfied for at least a threshold time. The threshold time is dependent on a change in a voltage of the wire harness coupled to a second side of the switch.

### I. CROSS REFERENCE TO RELATED APPLICATIONS

This application claims priority to U.S. provisional application Ser. No. 60/883,025, filed on Dec. 31, 2006, the contents of which are hereby incorporated by reference.

### II. BACKGROUND

The invention relates generally to electrical distribution systems and more particularly to the detection of and protection against harmful current increases in electrical distribution systems.

Electrical distribution systems, such as those typically employed in vehicles, utilize a wire harness for interconnecting devices to the electrical distribution system. The wire harness may include one or more wires for establishing electrical connections between devices in the electrical distribution system. For example, in an automobile the electrical distribution system may connect the battery to devices such as the starter, lights, and radio.

During operation, an electrical distribution system may be subject to a short. A short generally results from a significant drop in the impedance of a device connected to the electrical distribution system. Failure to detect a short may potentially damage the electrical distribution system or devices connected to the electrical distribution system.

### III. SUMMARY

In one respect, disclosed is a method for detecting a short in an electrical distribution system, the method comprising: determining whether a short condition is satisfied based on a change in a voltage in a wire harness coupled to a first side of a switch, and determining whether a short exists in response to a determination that the short condition has been satisfied for at least a threshold time, wherein the threshold time is dependent on a change in a voltage of the wire harness coupled to a second side of the switch.

In another respect, disclosed is a method for detecting a short in an electrical distribution system, the method comprising: determining whether a short condition is satisfied based on a mode of a first probe, wherein the first probe is coupled to a wire harness between a switch and a load; and determining whether a short exists in response to a determination that the short condition has been satisfied for at least a threshold time that is dependent on a mode of a second probe, wherein the second probe is coupled to the wire harness between a power supply and the switch.

In another respect, disclosed is a system for detecting a short in an electrical distribution system, comprising: a first probe coupled to a wire harness between a switch and a load; a second probe coupled to the wire harness between a power supply and the switch; a detection circuit, wherein the detection circuit is configured to determine whether a short condition is satisfied based on a mode of the first probe and to generate a shutdown signal for the switch in response to a determination that the short condition has been satisfied for at least a threshold time that is dependent on a mode of the second probe.

In yet another respect, disclosed is a detection circuit for detecting a short in an electrical distribution system, comprising: a first voltage comparator, wherein a first input of the first voltage comparator is a voltage measured by a first probe coupled to a wire harness between a switch and a load, and wherein a second input of the first voltage comparator is a first reference voltage; a second voltage comparator, wherein a first input of the second voltage comparator is a voltage measured by a second probe coupled to the wire harness between a power supply and the switch, and wherein a second input of the second voltage comparator is a second reference voltage; a filter configured to receive outputs from the first and second voltage comparators; a shutdown logic block configured to receive an output from the filter and generate a shutdown signal for the switch in response to a determination by the filter that a short condition has been satisfied for a period of time that is at least equal to a threshold time, wherein the short condition is dependent on the output of the first voltage comparator and the threshold time is dependent on the output of the second voltage comparator.

Numerous additional embodiments are also possible.

### IV. BRIEF DESCRIPTION OF THE DRAWINGS

Other objects and advantages of the invention may become apparent upon reading the detailed description and upon reference to the accompanying drawings.

FIG. 1 is a block diagram illustrating a system for detecting a short in an electrical distribution system, in accordance with one embodiment.

FIG. 2 is a block diagram illustrating a detection circuit for detecting a short in an electrical distribution system, in accordance with one embodiment.

FIG. 3 is a flow diagram illustrating a method for detecting a short in an electrical distribution system, in accordance with one embodiment.

FIG. 4 is a flow diagram illustrating a method for detecting a short in an electrical distribution system, in accordance with one embodiment.

FIG. 5 shows plots of voltage outputs versus time for a detection circuit for detecting a short in an electrical distribution system, in accordance with one embodiment.

FIG. 6 shows plots of voltage outputs versus time for a detection circuit for detecting a short in an electrical distribution system, in accordance with one embodiment.

While the invention is subject to various modifications and alternative forms, specific embodiments thereof are shown by way of example in the drawings and the accompanying detailed description. It should be understood, however, that the drawings and detailed description are not intended to limit the invention to the particular embodiment. This disclosure is instead intended to cover all modifications, equivalents, and alternatives falling within the scope of the present invention as defined by the appended claims.

### V. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

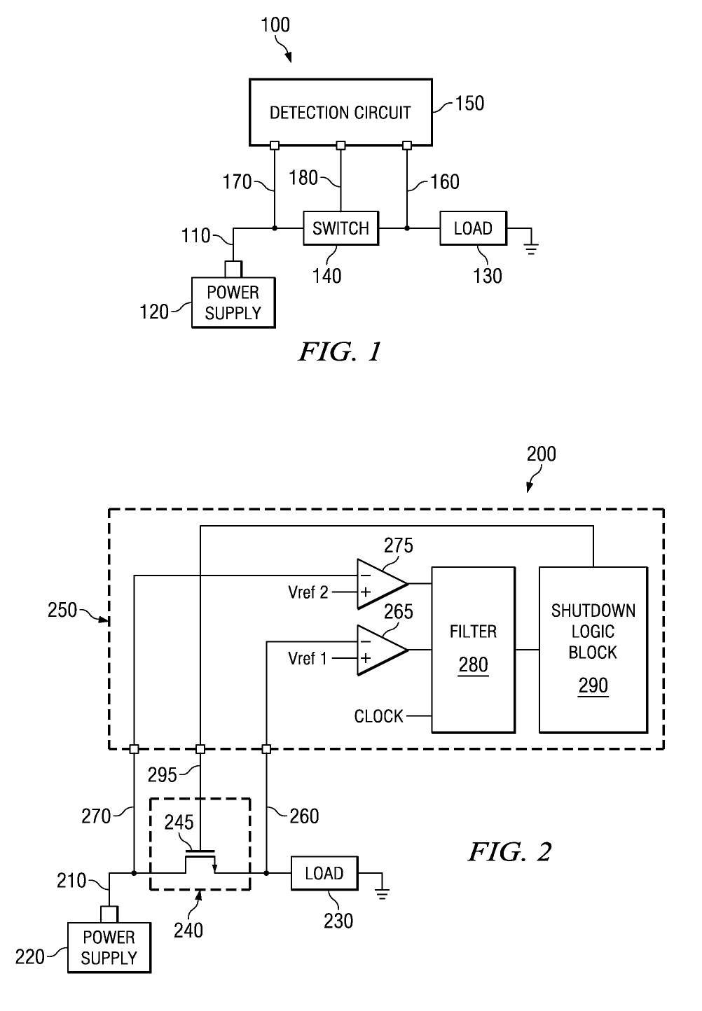

FIG. 1 is a block diagram illustrating a system for detecting a short in an electrical distribution system, in accordance with one embodiment. Electrical distribution system 100 includes a wire harness 110, which interconnects devices within electrical distribution system 100. Wire harness 110 may include one or more wires for establishing electrical connections or couplings between devices in electrical distribution system 100. Wire harness 110 may also include other cables bundled with electrical wires, such as data cables for establishing data connections between devices in electrical distribution system 100. In one embodiment, electrical distribution system 100 may be the electrical distribution system of an automobile.

In the illustrated embodiment, switch 140 is coupled to wire harness 110 between power supply 120 and load 130, and load 130 is connected to ground. Power supply 120 may be a battery, such as a car battery. Load 130 may generally be any device coupled to wire harness 110 that carries a load, such as a light bulb, an electric motor, or a heater. In some embodiments, devices, such as load 130, may be coupled to wire harness 110 using termination connectors. Switch 140 may be any device that is configured to interrupt the current between power supply 120 and load 130 in response to an interrupt signal. In one embodiment, switch 140 may be a transistor such as a field effect transistor (FET).

During operation, an electrical distribution system may be subject to an overcurrent event that causes an increased current to flow through the wire harness and devices in the electrical distribution system. A short is a harmful overcurrent event that can potentially damage the components of an electrical distribution system. A short can cause an excessive current to flow through a battery. This can cause a rapid build up of heat in the battery, which can lead to an explosion. Overloaded wires in a wire harness can also overheat, which can damage the wires' insulation and the wire harness. A short generally results from a significant drop in the impedance of a component of an electrical distribution system. However, an increase in current does not automatically indicate a short. Overcurrent events that do not harm an electrical distribution system can be defined as glitches. For example, glitches can arise from noise and faulty loads that may produce random or intermittent current increases that are not harmful. Nevertheless, such glitches can be misinterpreted as shorts if the sensitivity of a detection system is too high.

Returning to FIG. 1, detection circuit 150 is shown coupled to probe 160 and probe 170, which in turn are coupled to wire harness 110. Probe 160 is coupled to wire harness 110 on the load side of switch 140, while probe 170 is coupled to wire harness 110 on the power supply side of switch 140. Probe 160 is configured to detect a voltage at a point along wire harness 110 between switch 140 and load 130. Probe 170 is configured to detect a voltage at a point along wire harness 110 between power supply 120 and switch 140. Probes 160 and 170 allow voltage changes to be monitored on either side of switch 240. In one embodiment, probes 160 and 170 are wires that pass the voltages at points on either side of switch 140 to detection circuit 150.

An overcurrent event on wire harness 110 on the load side of switch 140 may generate a current increase that may produce a change in voltage at probe 160 and a change in voltage at probe 170. The parasitic inductance of wire harness 110 may affect such voltage changes as a result of the time dependent nature of the overcurrent event. As noted above, the overcurrent event may indicate a short. For example, a short might be caused by load 130 breaking down. In the case of a dead short, the impedance of load 130 effectively drops to zero, and wire harness 110 at the left hand side of load 130 is shorted to ground. However, the overcurrent event may also be due to a glitch in load 130. In the case of a short, the short may be characterized as a fast short or slow short depending on how quickly the impedance of load 130 decreases. Detection circuit 150 may be configured to detect and differentiate between fast and slow shorts and filter out glitches.

Detection circuit 150 is configured to detect a short if a short condition has been satisfied for a period of time that is equal to or greater than a threshold time. A short condition may be defined that depends on the change in voltage of probe 160 between steady state operation and during an overcurrent event. An upper limit on the change in voltage may be determined based on the characteristics of wire harness 110. If the change equals or exceeds the upper limit, the short condition is satisfied. The mode of probe 160 is determined based on whether the short condition is satisfied. When the short condition is satisfied, the mode of probe 160 is high. If the short condition is not satisfied, the mode of probe 160 is low.

A threshold time may be defined that depends on the change in the voltage measured by probe 170 between steady state operation and during an overcurrent event. An upper limit on the change in voltage of probe 170 may be determined based on the characteristics of wire harness 110. The upper limit for the voltage change for probe 170 may be the same or different than the upper limit set for probe 160. A first threshold time is determined for the case where the voltage change equals or exceeds the upper limit for probe 170. A second threshold time is determined for the case where the voltage change fails to exceed the upper limit. Values for the threshold times may generally be determined based on the characteristics of the wire harness. The first threshold time, which may represent a fast short, is preferably less than the second threshold time, which may represent a slow short.

Detection circuit 150 is configured to generate and send a shutdown signal that may be used to turn off switch 140. The shutdown signal may be transmitted to switch 140 through coupling 180. In one embodiment, switch 140 includes a control circuit that is configured to turn off switch 140 in response to receiving the shutdown signal. In another embodiment, detection circuit 150 may include a control circuit configured to control the turning off of switch 140. In yet another embodiment, detection circuit 150 may be coupled indirectly to switch 140 via an external control circuit. In this case, detection circuit 150 may send the shutdown signal to the external control circuit, and the external control circuit may control the turning off of switch 140.

FIG. 2 is a block diagram illustrating a detection circuit for detecting a short in an electrical distribution system, in accordance with one embodiment. As shown in FIG. 2, electrical distribution system 200 includes a wire harness 210 having a switch 240 coupling a power supply 220 to a load 230, and load 230 is grounded. Wire harness 210, power supply 220, load 230, and switch 240 have properties that are similar to like-named elements as illustrated in FIG. 1 and as described above in reference to FIG. 1. As shown in FIG. 2, switch 240 may include FET 245.

Detection circuit 250 is shown coupled to probe 260 and probe 270, which in turn are coupled to wire harness 210. Probe 260 is coupled to wire harness 210 on the load side of switch 240, while probe 270 is coupled to wire harness 210 on the power supply side of switch 240. Probe 260 is configured to detect a voltage at a point along wire harness 210 between switch 240 and load 230. Probe 270 is configured to detect a voltage at a point along wire harness 210 between power supply 220 and switch 240. Probes 260 and 270 allow voltage changes to be monitored on either side of switch 240. In one embodiment, probe 260 may be coupled to the source of FET 245, and probe 270 may be coupled to the drain of FET 245.

Voltage comparator 265 is shown in FIG. 2 having a first input given by the voltage measured by probe 260 and a second input given by a reference voltage V_{ref1}. Voltage comparator 275 is illustrated with a first input given by the voltage measured by probe 270 and a second input given by a reference voltage V_{ref2}. In an alternative embodiment, the first input to voltage comparator 275 may be the difference between the voltage measured at probe 270 and the steady state voltage at probe 270. In one embodiment, the mode of probe 260 is defined as high if the output of voltage comparator 265 is high, which will occur when the first input of voltage comparator 265 is greater than V_{ref1}. The mode of probe 260 is defined as low if the output of voltage comparator 265 is low, which occurs when the first input of voltage comparator 265 is less than V_{ref1}. Similarly, the mode of probe 270 is defined as high if the first input of voltage comparator 275 is greater than V_{ref2}, (i.e., the output of voltage comparator 265 is high) and the mode of probe 270 is defined as low if the first input of voltage comparator 275 is less than V_{ref2} (i.e., the output of voltage comparator 275 is low).

An overcurrent event on wire harness 210 on the load side of switch 240 may generate a current increase that may produce voltage changes at probes 260 and 270. By monitoring voltage changes on either side of switch 240, detection circuit 250 can detect and differentiate between fast and slow shorts and filter out glitches.

Detection circuit 250 is configured to detect a short if a short condition has been satisfied for a period of time that is equal to or greater than a threshold time. A short condition may be defined that depends on the output of voltage comparator 265. If the output of voltage comparator 265 is high, the short condition is satisfied. If the output of voltage comparator 265 is low, the short condition is not satisfied.

As shown in FIG. 2, filter 280 is coupled to voltage comparators 265 and 275. Filter 280 is configured to receive the output of voltage comparator 265 and the output of voltage comparator 275. Filter 280 is generally operable to determine if the short condition has been satisfied for a period of time that is at least equal to a threshold time, where the short condition is dependent on the output of voltage comparator 265 as described above and the threshold time is dependent on the output of voltage comparator 275 as described below. In one embodiment, filter 280 is a programmable filter. If filter 280 determines that the short condition has been satisfied for at least the threshold time, the output of filter 280 is defined to be high. Alternatively, if the short condition has not been satisfied for at least the threshold time, the output of filter 280 is defined to be low.

A threshold time may be defined that depends on the output of voltage comparator 275. A first threshold time is determined for the case where the output voltage is high. A second threshold time is determined for the case where the output voltage is low. In general, the possibility of a short existing is greater when the output voltage of voltage comparator 275 is high than in the case where the output voltage is low. Consequently, the threshold time for the case where the output voltage of voltage comparator 275 is high is preferably selected to be less than the threshold time determined for the case where the output voltage of voltage comparator 275 is low. Values for the threshold times are generally determined based on the characteristics of wire harness 210, power supply 220, load 230, and switch 240. In one embodiment, the value of the first threshold time is determined to correspond to a fast short scenario, and the value of the second threshold time is determined to correspond to a slow short scenario.

In one embodiment, filter 280 includes a digital filter. In this case, filter 280 may include a counter for measuring the time using a clock signal input to filter 280 from a clock signal generator. In another embodiment, filter 280 may include an analog filter. An exemplary analog filter may include one or more resistor-capacitor (RC) circuits where the threshold times may be set by appropriately adjusting the time constants of the one or more RC circuits.

Referring to FIG. 2, shutdown logic block 290 is shown coupled to filter 280. Shutdown logic block 290 is configured to receive the output from filter 280 and to generate a shutdown signal to turn off switch 240 if the output received from filter 280 is high. The shutdown signal may be transmitted to switch 240 through coupling 295. In one embodiment, switch 240 includes a control circuit for turning off switch 240 in response to receiving the shutdown signal. In another embodiment, detection circuit 250 may include a control circuit for controlling the turning off of switch 240. In yet another embodiment, detection circuit 250 may be coupled indirectly to switch 240 via an external control circuit. In this case, detection circuit 250 may send the shutdown signal to the external control circuit, and the external control circuit may control the shut down of switch 240.

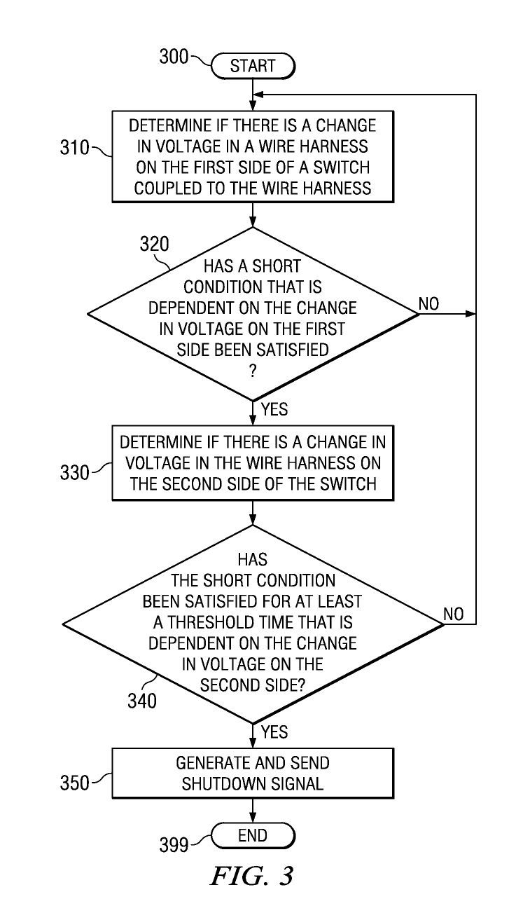

FIG. 3 is a flow diagram illustrating a method for detecting a short in an electrical distribution system, in accordance with one embodiment. Processing begins at 300. The method depicted in FIG. 3 may include one or more of the operations shown in blocks 310-350. In block 310 a determination is made as to whether there is a change in voltage in a wire harness on the first side of a switch coupled to the wire harness. The wire harness may be any wire harness used to interconnect elements in an electrical distribution system. In one embodiment, the wire harness may be wire harness 110 used in electrical distribution system 100, and the switch may be switch 140. A voltage at a location on the wire harness on the first side of the switch can be monitored using a detection circuit such as detection circuit 150 that is coupled to the wire harness. The detection circuit may be coupled to wire harness via a connector or sensor, such as probe 160. In one embodiment, the voltage may be measured proximate to the first side of the switch. For example, if the switch includes an FET, the first side of the switch may correspond to the source side of the FET, and the voltage may be measured at the source of the FET.

At block 320 a short condition is examined that is used to identify the possibility of a short in the wire harness. A short condition may be defined that depends on the change in voltage of the wire harness on the first side of the switch between steady state operation and during an overcurrent event. In one embodiment, the change in voltage in the harness on the first side of the switch can be determined by comparing the measured voltage to a first reference voltage. In another embodiment, an upper limit on the change in voltage may be determined based on the characteristics of the wire harness. If the change equals or exceeds the upper limit, the short condition is satisfied. If the short condition is not satisfied, processing returns to block 310. In this case, the change in voltage in the wire harness on the first side of the switch resulting from the overcurrent event represents a glitch. If the short condition is satisfied, the possibility of a short exists and processing continues with block 330.

At block 330, the change in voltage on the second side of the switch is determined. A voltage at a location on the wire harness on the second side of the switch can be monitored using a detection circuit such as detection circuit 150 that is coupled to the wire harness at a position on the wire harness that is on the second side of the switch. The detection circuit may be coupled to wire harness via a connector or sensor, such as probe 170. In one embodiment, the voltage may be measured proximate to the second side of the switch. For example, if the switch includes an FET, and the first side of the switch corresponds to the source side of the FET, the second side will correspond to the drain side of the FET, and the voltage on the second side may be measured at the drain of the FET.

Once the voltage in the wire harness on the second side of the switch is determined, a determination is made at block 340 as to whether the short condition has been satisfied for a period of time that is at least equal to a threshold time, where the threshold time depends on the change in voltage in the wire harness on the second side of the switch. A threshold time may be defined that depends on the change in voltage of the wire harness on the second side of the switch between steady state operation and during an overcurrent event. In one embodiment, the change in voltage in the harness on the second side of the switch can be determined by comparing the measured voltage to a second reference voltage. In another embodiment, an upper limit on the change in voltage may be determined based on the characteristics of the wire harness. The upper limit for voltage change for the harness measured on the second side of the switch may be the same or different than the upper limit set the voltage change for the harness measured on the first side of the switch. A first threshold time is determined for the case where the voltage change equals or exceeds the upper limit for voltage change for the harness measured on the second side of the switch. A second threshold time is determined for the case where the voltage change fails to exceed such upper limit. Values for the threshold times may generally be determined based on the characteristics of the wire harness. The first threshold time, which may represent a fast short, is preferably less than the second threshold time, which may represent a slow short.

Returning to FIG. 3, if it is determined at block 340 that the short condition has not been satisfied for at least the threshold time, processing returns to block 310. Conversely, if the short condition is satisfied for a period of time that equals or exceeds the threshold time, processing continues at block 350. At block 350, if a short has been detected, a shutdown signal is generated and sent to turn off the switch. In one embodiment, the shutdown signal may be generated and sent using a detection circuit. An example of an appropriate detection circuit is detection circuit 150.

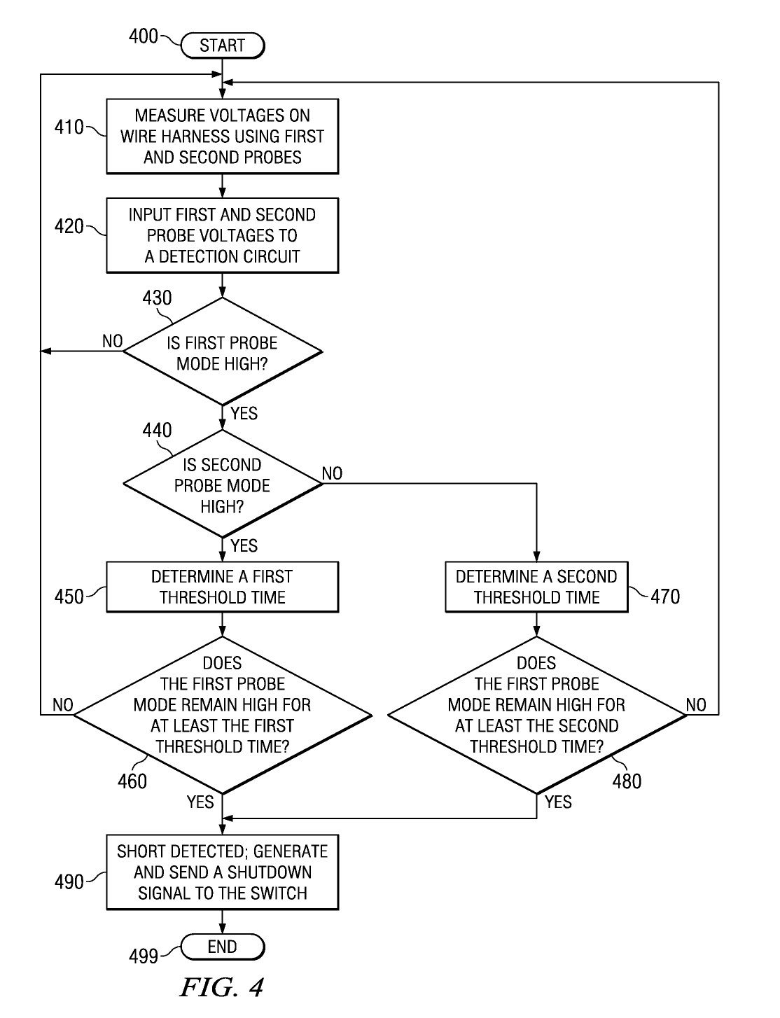

FIG. 4 is a flow diagram illustrating a method for detecting a short in an electrical distribution system, in accordance with one embodiment. The method depicted in FIG. 4 may include one or more of the operations shown in blocks 410-490. Processing begins at 400 and continues at block 410 where voltage measurements are made on a wire harness at locations on either side of a switch using first and second probes. In one embodiment, the method illustrated in FIG. 4 may be implemented in electrical distribution system 200 as shown in FIG. 2 in which case the probes may be probes 260 and 270, the wire harness may be wire harness 210, and the switch may be switch 240. The probes are coupled to the wire harness on either side of a switch coupling a power supply, such as power supply 220, to a load, such as load 230, with the first probe coupled to the power supply side, and the second probe coupled to the load side. In one embodiment, the switch may include an FET, such as FET 245, having a drain coupled to the wire harness on the power supply side of the switch and a source coupled to the wire harness on the load side of the switch. The first probe may be coupled to the source of the FET, and the second probe may be coupled to the drain of the FET.

After voltages on the wire harness are measured by the first and second probes, these first and second probe voltages are input into a detection circuit at block 420. In one embodiment, the detection circuit may be detection circuit 250, and the first and second probes may be probes 260 and 270, respectively. In one embodiment, the first and second probes may be wires coupling the detection circuit to the wire harness. More generally, the first and second probes may be any electrical devices operable to input the voltages on the wire harness measured at the locations where the probes are coupled to the wire harness to the detection circuit.

Referring to FIG. 4, processing continues at block 430 where a determination is made as to the mode of the first probe. The mode of the first probe depends on the change in voltage of the wire harness on the power supply side of the switch between steady state operation and during an overcurrent event. In one embodiment, the mode of the first probe is defined to be high if the voltage on the harness measured by the first probe is greater than a first reference voltage. In this case, if the voltage on the harness measured by the first probe is not greater than the first reference voltage, the mode of the first probe is defined to be low. Alternatively, the mode of the first probe may be defined to be high if the voltage on the harness measured by the first probe is equal to or greater than the first reference voltage. In this case, the mode of the first probe is defined to be low if the voltage on the harness measured by the first probe is less than the first reference voltage. Voltage comparator 265, which is illustrated in FIG. 2, may be used to implement such an embodiment. In an alternative embodiment, the mode of the first probe may be defined to be high if the voltage on the harness measured by the first probe is less than the first reference voltage.

If the mode of the first probe is determined to be low, processing returns to block 410. If the mode of the first probe is determined to be high, processing continues at block 440 where the mode of the second probe is determined. The mode of the second probe depends on the change in voltage of the wire harness on the power supply side of the switch between steady state operation and during an overcurrent event. In one embodiment, the mode of the second probe is defined to be high if the voltage on the harness measured by the second probe is greater than a second reference voltage. In this case, if the voltage on the harness measured by the second probe is not greater than the second reference voltage, the mode of the second probe is defined to be low. Alternatively, the mode of the second probe may be defined to be high if the voltage on the harness measured by the second probe is equal to or greater than the second reference voltage. In this case, the mode of the second probe is defined to be low if the voltage on the harness measured by the second probe is less than the second reference voltage. Voltage comparator 275, which is illustrated in FIG. 2, may be used to implement such an embodiment. In an alternative embodiment, the mode of the second probe may be defined to be high if the voltage on the harness measured by the second probe is less than the second reference voltage.

In one embodiment, the mode of the first probe is determined prior to determining the mode of second probe. In an alternative embodiment, the mode of the second probe may be determined prior to the mode of the first probe. In yet another embodiment, the modes of the first and second probes may be determined at the same time.

As shown in FIG. 4, if the mode of the second probe is determined to be high in block 440, then a first threshold time is determined in block 450. When the mode of the second probe goes high, the possibility of a short existing is greater than in the case where the mode of the second probe is low. A suitable first threshold time may be determined based on the characteristics of the wire harness, the power supply, the switch, and the load. After the first threshold time is determined, processing continues at block 460 where a determination is made as to whether the mode of the first probe remains high for at least the first threshold time. This determination indicates whether a short is detected. If the mode of the first probe does not remain high for at least the first threshold time, a short is not detected and processing returns to block 410. In this case, the overcurrent event that caused the mode of the first probe to go high represents a glitch. If the mode of the first probe does remain high for at least the first threshold time, processing continues at block 490.

Returning to FIG. 4, if the mode of the second probe is not high in block 440, processing is passed to block 470, and a second threshold time is determined. As noted above, the second threshold time is preferably determined to be less than the first threshold time. In one embodiment, the determination of whether the first probe mode remains high for the first or second threshold times may be implemented using a filter, such as filter 280. After the second threshold time is determined, processing continues at block 480 where a determination is made as to whether the mode of the first probe remains high for at least the second threshold time. If the mode of the first probe does not remain high for at least the second threshold time, a short is not detected and processing returns to block 410. As in the case above, this represents a glitch.

If the mode of the first probe does remain high for at least the second threshold time, processing continues at block 490. At block 490, if a short has been detected, a shutdown signal is generated and sent to turn off the switch. In one embodiment, the shutdown signal may be generated and sent using a detection circuit. An example of an appropriate detection circuit is detection circuit 250, where the shutdown signal is generated and sent using shutdown logic block 290. Processing subsequently ends at 499.

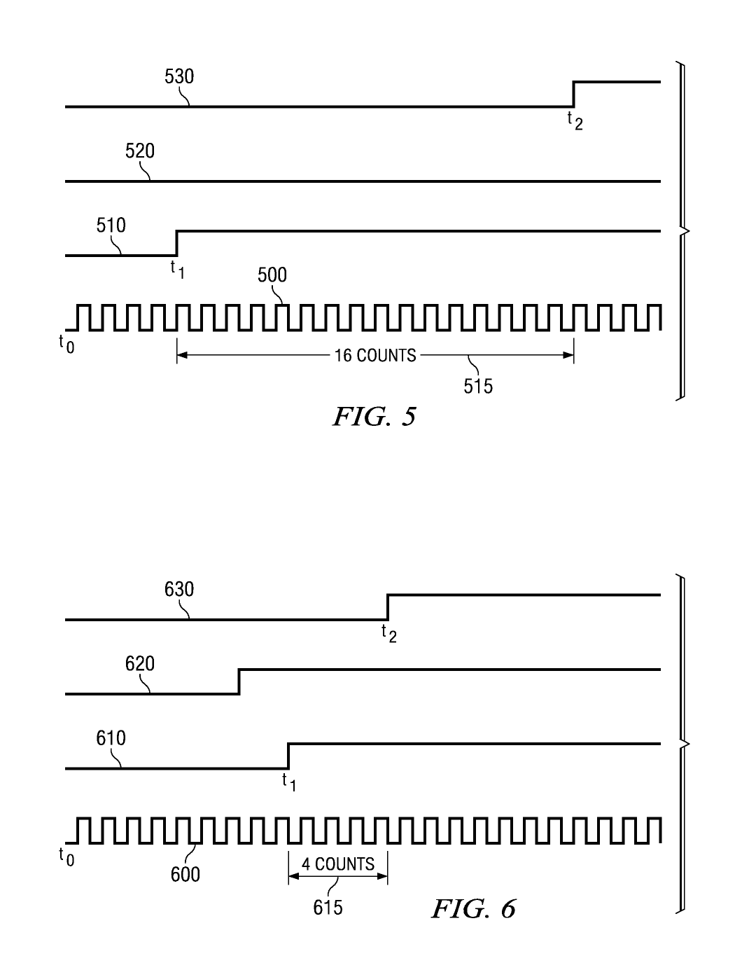

FIG. 5 shows plots of voltage outputs versus time for a detection circuit for detecting a short in an electrical distribution system, in accordance with one embodiment. The plots in FIG. 5 will be described with reference to electrical distribution system 200 illustrated in FIG. 2. The plots illustrate the operation of detection circuit 250 for a case in which the mode of probe 260 goes high and the mode of probe 270 is low. Output voltages versus time are illustrated for various components in electrical distribution system 200 for an embodiment in which filter 280 is a digital filter. In one embodiment, filter 280 may include a counter that is configured to measure time using a clock signal input into filter 280. Plot 500 shows a clock signal used to measure time in filter 280.

Plot 510 shows the output of voltage comparator 265 when the mode of probe 260 goes high. At time to electrical distribution system 200 is operating with normal steady state current flow through wire harness 210. An overcurrent event occurs at time t₁ that causes probe 260 to go high. This in turn will cause the output of voltage comparator 265 to go high at time t₁, as illustrated in plot 510, which indicates that a short condition has been satisfied. Once the output of voltage comparator 265 goes high, the counter will begin counting at time t₁. The threshold time used by filter 280 will be determined based on the output of voltage comparator 275 at time t₁. For the illustrated embodiment, the mode of probe 270 is low at time t₁ as shown in Plot 520, which means that the output of voltage comparator 275 will be low and the second threshold time for filter 280 will be used. For the embodiment illustrated in FIG. 5, second threshold time 515 is 16 counts. In one embodiment, a requirement for detecting a short is that the short condition is satisfied for a time that is at least equal to the threshold time. For the illustrated embodiment, this will be the case if the output of filter 280 goes high, which will occur if the output of voltage comparator 265 remains high for at least 16 counts after the output of voltage comparator 265 goes high at time t₁. This occurs at time t2, and the output of filter 280 goes high at this time as indicated in plot 530.

FIG. 6 shows plots of voltage outputs versus time for a detection circuit for detecting a short in an electrical distribution system, in accordance with one embodiment. The plots in FIG. 6 will be described with reference to electrical distribution system 200 illustrated in FIG. 2. The plots illustrate the operation of detection circuit 250 for a case in which the mode of probe 260 goes high and the mode of probe 270 is high. Output voltages versus time are illustrated for various components in electrical distribution system 200 for an embodiment in which filter 280 is a digital filter. Plot 600 shows a clock signal used to measure time in filter 280.

Plot 610 shows the output of voltage comparator 265 when the mode of probe 260 goes high. At time to electrical distribution system 200 is operating with normal steady state current flow through wire harness 210. An overcurrent event occurs at time t₁ that causes probe 160 to go high. This in turn will cause the output of voltage comparator 265 to go high at time t₁, as illustrated in plot 610, which indicates that a short condition has been satisfied. Once the output of voltage comparator 265 goes high, the counter will begin counting at time t₁. The threshold time used by filter 280 will be determined based on the output of voltage comparator 275 at time t₁. For the illustrated embodiment, the mode of probe 270 is high at time t₁ as shown in Plot 620, which means that the output of voltage comparator 275 will be high and the first threshold time for filter 280 will be used. For the embodiment illustrated in FIG. 6, first threshold time 615 is 4 counts. In one embodiment, a requirement for detecting a short is that the short condition is satisfied for a time that is at least equal to the threshold time. For the illustrated embodiment, this will be the case if the output of filter 280 goes high, which will occur if the output of voltage comparator 265 remains high for at least 4 counts after the output of voltage comparator 265 is determined to be high at time t₁. This occurs at time t2, and the output of filter 280 goes high at this time as indicated in plot 630.

Those of skill will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Those of skill in the art may implement the described functionality in varying ways for each particular application, but such implementation decisions should not be interpreted as causing a departure from the scope of the present invention.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A method for detecting a short in an electrical distribution system, comprising:
determining whether a short condition is satisfied based on a change in a voltage in a wire harness coupled to a first side of a switch; and
determining whether a short exists in response to a determination that the short condition has been satisfied for at least a threshold time, wherein the threshold time is dependent on a change in a voltage of the wire harness coupled to a second side of the switch.

2. The method of claim 1, comprising sending a shutdown signal for the switch in response to determining that a short exists.

3. The method of claim 1, wherein the short condition comprises the change in the voltage in the wire harness coupled to the first side of the switch being equal to or greater than a first upper limit.

4. The method of claim 1, wherein the threshold time is set to a first threshold time if the change in the voltage in the wire harness coupled to the second side of the switch is equal to or greater than a second upper limit and the threshold time is set to a second threshold time if the change in the voltage in the wire harness coupled to the second side of the switch is less than the second upper limit.

5. The method of claim 4, wherein the first threshold time is less than the second threshold time.

6. The method of claim 1, wherein the wire harness comprises one or more wires.

7. The method of claim 1, wherein the first side of the switch is coupled to a load, and the second side of the switch is coupled to a power supply.

8. The method of claim 1, wherein the change in the voltage in the wire harness coupled to the first side of the switch is determined by comparing a voltage at a position on the wire harness on the first side of the switch to a first reference voltage and the change in the voltage in the wire harness coupled to the second side of the switch is determined by comparing a voltage at a position on the wire harness on the second side of the switch to a second reference voltage.

9. A method for detecting a short in an electrical distribution system, the method comprising:
determining whether a short condition is satisfied based on a mode of a first probe, wherein the first probe is coupled to a wire harness between a switch and a load; and
determining whether a short exists in response to a determination that the short condition has been satisfied for at least a threshold time that is dependent on a mode of a second probe, wherein the second probe is coupled to the wire harness between a power supply and the switch.

10. The method of claim 9, comprising sending a shutdown signal for the switch in response to determining that a short exists.

11. The method of claim 9, wherein the short condition comprises the mode of the first probe being high.

12. The method of claim 9, wherein the mode of the first probe is determined by comparing a voltage of the first probe to a first reference voltage and the mode of the second probe is determined by comparing a voltage of the second probe to a second reference voltage.

13. The method of claim 9, wherein the threshold time is set to a first threshold time if the mode of the second probe is high and the threshold time is set to a second threshold time if the mode of the second probe is low.

14. The method of claim 13, wherein the first threshold time is less than the second threshold time.

15. A system for detecting a short in an electrical distribution system, comprising:
a first probe coupled to a wire harness between a switch and a load;
a second probe coupled to the wire harness between a power supply and the switch;
a detection circuit, wherein the detection circuit is configured to:
determine whether a short condition is satisfied based on a mode of the first probe, and
generate a shutdown signal for the switch in response to a determination that the short condition has been satisfied for at least a threshold time that is dependent on a mode of the second probe.

16. The system of claim 15, wherein the detection circuit comprises:
a first voltage comparator, wherein a first input of the first voltage comparator is a voltage measured by the first probe and a second input of the first voltage comparator is a first reference voltage, and wherein the output of the first voltage comparator determines the mode of the first probe;
a second voltage comparator, wherein a first input of the second voltage comparator is a voltage measured by the second probe and a second input of the first voltage comparator is a second reference voltage, and wherein the output of the second voltage comparator determines the mode of the second probe;
a filter configured to receive outputs from the first and second voltage comparators and determine if the short condition has been satisfied for at least the threshold time;
a shutdown logic block configured to:
receive an output from the filter, and
generate a shutdown signal for the switch if the output from the filter is high.

17. The system of claim 16, wherein the filter uses a clock signal to determine if the short condition has been satisfied for at least the threshold time.

18. The system of claim 16, wherein the filter comprises an analog filter.

19. The system of claim 18, wherein the analog filter includes one or more resistor-capacitor (RC) circuits.

20. The system of claim 15, wherein the short condition comprises the mode of the first probe being high.

21. The system of claim 15, wherein the threshold time is a first threshold time if the mode of the second probe is high and the threshold time is a second threshold time if the mode of the second probe is low.

22. The system of claim 21, wherein the first threshold time is less than the second threshold time.

23. The system of claim 15, wherein the switch is a field effect transistor (FET).

24. The system of claim 23, wherein the first probe is coupled to a source of the FET and the second probe is coupled to the drain of a FET.
